(19) United States
(12) Patent Application Publication
(10) Pub. No.: US 2015/0207528 A1
(43) Pub. Date: Jul. 23, 2015

(54) BAND-LIMITED DIFFERENTIATOR FOR GRID APPLIANCE CONTROLLERS

(71) Applicant: David P. Chassin, Pasco, WA (US)

(72) Inventor: David P. Chassin, Pasco, WA (US)

(73) Assignee: BATTELLE MEMORIAL INSTITUTE, Richland, WA (US)

(21) Appl. No.: 14/539,436

(22) Filed: Nov. 12, 2014

Related U.S. Application Data
(60) Provisional application No. 61/929,594, filed on Jan. 21, 2014.

(51) Int. Cl. H04B 1/10; G01R 21/00

(52) U.S. Cl. CPC H04B 1/1018; G01R 21/00

(57) ABSTRACT

A method and device for measuring electrical grid data in the presence of noise is disclosed. Noisy frequency data is received from the grid. The noisy data is filtered above a predetermined frequency. The filtered data is differentiated using band-limited differentiator. The data may be filtered and differentiated simultaneously by the band-limited differentiator.

### CROSS-REFERENCE TO RELATED APPLICATIONS

This application claims priority to U.S. Provisional Application Ser. No. 61/929,594, filed Jan. 21, 2014, titled “BAND-LIMITED DIFFERENTIATOR DESIGN FOR GRID FRIENDLY CONTROLLERS,” hereby incorporated by reference in its entirety for all of its teachings.

### STATEMENT REGARDING FEDERALLY SPONSORED RESEARCH OR DEVELOPMENT

This invention was made with Government support under Contract DE-AC0576RLO1830 awarded by the U.S. Department of Energy. The Government has certain rights in the invention.

### TECHNICAL FIELD

This invention relates to digital differentiators. More specifically, this invention relates to band-limited digital differentiators for control of grid friendly appliances.

### BACKGROUND

Frequency control plays an important role in preserving the power balance of a multi-machine power system, such as an electrical grid. Power system frequency drops when supply from generators falls below demand. When the change in frequency is large, the reduction in supply can trigger protection systems that may result in system separation, loss of load, and customer outages.

Grid friendly appliance controllers detect underfrequency events in the home and turn off the appliance in response to a system event. However, local noise that may emanate from induction motors and switched power electronic equipment can mask the slower changes in grid frequency that the controller is designed to respond to.

What is needed is an improved device and/or method of determining frequency for grid friendly appliance controllers.

### SUMMARY

The present invention is directed to methods and devices for measuring electrical grid data in the presence of noise. In one embodiment, the method includes receiving noisy data from the grid. The method also includes filtering the noisy data above a predetermined frequency. The method further includes differentiating the filtered data using a band-limited differentiator.

In one embodiment, the data is filtered and differentiated simultaneously by the band-limited differentiator.

The differentiator returns the derivative of the filtered data.

In one embodiment, the predetermined frequency for cutting off noise from the noisy data is at least 0.5 Hz.

In one embodiment, the filtered and differentiated data is used by a grid appliance controller.

The noisy data includes, but is not limited to, frequency signals, voltage signals, and/or current signals.

In one embodiment, the method further includes estimating inertia of the electrical grid as a function of load.

In one embodiment, the method further includes measuring zero-crossing times of approximately 60 Hz AC power in homes.

In one embodiment, the method measures instantaneous AC voltage or currents from the grid.

The band-limited differentiator can be a band-limited digital differentiator.

In another embodiment of the present invention, a device for measuring electrical grid data in the presence of noise is disclosed. The device includes a band-limited differentiator for filtering noisy data from the grid above a predetermined frequency and differentiating the filtered data. The device also includes a grid friendly appliance controller including the band-limited differentiator. In one embodiment, the differentiator is a digital differentiator.

In another embodiment of the present invention, a method of measuring electrical grid data in the presence of noise is disclosed. The method includes receiving noisy frequency data from the grid; filtering the noisy frequency data above a frequency of at least 0.5 Hz; and differentiating the filtered data using a band-limited digital differentiator, wherein the data is filtered and differentiated simultaneously by the band-limited digital differentiator.

### BRIEF DESCRIPTION OF THE DRAWINGS

FIG. 1A is a graph of frequency with respect to time for a synthetic input signal of raw data.

FIG. 1B is a graph of acceleration with respect to time, which is the derivative of the input signal of FIG. 1A.

FIG. 2A is a graph showing a true input signal of FIG. 1A in the presence of noise—or measured signal—with respect to time.

FIG. 2B is a graph showing the output of a conventional differentiator with respect to time of the noisy input signal shown in FIG. 2A.

FIG. 3 is a graph showing the output of the band-limited differentiator of the present invention for the true and measured input signals.

FIG. 4A shows the frequency changes for a real frequency measured at 60 Hz using the band-limited differentiator of the present invention with a conventional 0.5 Hz low-pass filter.

FIG. 4B shows the derivative of the filtered signal of FIG. 5A using the band-limited differentiator of the present invention.

### DETAILED DESCRIPTION OF THE PREFERRED EMBODIMENTS

The following description includes the preferred best mode of embodiments of the present invention. It will be clear from this description of the invention that the invention is not limited to these illustrated embodiments but that the invention also includes a variety of modifications and embodiments thereto. Therefore the present description should be seen as illustrative and not limiting. While the invention is susceptible of various modifications and alternative constructions, it should be understood, that there is no intention to limit the invention to the specific form disclosed, but, on the contrary, the invention is to cover all modifications, alternative constructions, and equivalents falling within the spirit and scope of the invention as defined in the claims.

The present invention includes methods and devices using a novel band-limited differentiator for applications that use, for example, grid appliance controllers to better regulate electrical power supply and demand.

In one embodiment, the band-limited digital differentiator has an odd length N and the transfer function is:

H(z)=h₀+h₁z⁻¹+ . . . +h_{N-1}z^{-(N-1)}

The coefficients are assumed anti-symmetric, i.e.:

h_{(N-1)/2}=0 and hₙ=−h_{N-1-n} for n=0, 1, . . . , (N−1)/2

so that:

H(e^{jω})=e^{-jωM}·j·x^{T}s(ω)

where:
M=(N−1)/2 is the number of design variables;
x=[x₁ x₂ . . . x_{M}]^{T} are the design variables in vector form;
xₘ=2h_{M-m} for m=1, 2, . . . M are the individual variables; and
s(ω)=[sin ω sin 2ω . . . sin Mω]^{T} is the frequency band vector.

The design of the band-limited digital differentiator can then be described by the optimization problem:

$$minimize J ( x ) = {\int }_{0}^{{ω}_{p}} {[ {x}^{T} s ( ω ) - ω / {T}_{s} ]}^{2} d ω + {\int }_{{ω}_{a}}^{π} {[ {x}^{T} s ( ω ) ]}^{2} d ω$$

where ωₚ and ωₐ are the passband and stopband edges, respectively, and Tₛ is the sampling interval in second of the signal to be differentiated. To solve this optimization problem using conventional methods J(x) is presented in the standard form:

J(x)=x^{T}Qx−2x^{T}p+constant

The global minimizer is given by:

x*=Q⁻¹p

from which an optimal band-limited differentiator is obtained.

The objective function can be transformed into the standard form by rearranging it as:

$$\begin{matrix}J ( x ) = {x}^{T} [ {\int }_{0}^{{ω}_{p}} s ( ω ) {s ( ω )}^{T} d ω + {\int }_{{ω}_{a}}^{π} s ( ω ) {s ( ω )}^{T} d ω ] x & - 2 {x}^{T} [ \frac{1}{{T}_{s}} {\int }_{{ω}_{a}}^{π} ω s ( ω ) d ω ] & + \frac{1}{{T}_{s}^{2}} {\int }_{0}^{{ω}_{p}} {ω}^{2} d ω \\ = {x}^{T} Qx & - 2 {x}^{T} p & + constant\end{matrix}$$

so that the following is found:

Q=∫₀^{ω}^{ₚ}s(ω)s(ω)^{T}dω+∫_{ω}_{ₐ}^{π}s(ω)s(ω)^{T}dω

and

$$p = \frac{1}{{T}_{s}} {\int }_{0}^{{ω}_{p}} ω s ( ω ) d ω$$

Integrating the member (m, n) of Q when m≠n over the interval [a, b] gives:

$${q}_{m , n} = \frac{1}{2} [ \frac{sin ( ( m - n ) b ) - sin ( ( m - n ) a )}{m - n} - \frac{sin ( ( m + n ) b ) - sin ( ( m + n ) a )}{m + n} ]$$

When m=n, this results in:

$${q}_{m , m} = \frac{b - a}{4} - \frac{sin ( 2 mb ) - sin ( 2 ma )}{8 m}$$

Integrating the member (m) of p over the interval [a, b] gives:

$${p}_{m} = \frac{sin mb - mb cos mb - sin ma + ma cos ma}{{T}_{s} {m}^{2}}$$

### EXAMPLE

The following serves to illustrate certain embodiments and aspects of the present invention and are not to be construed as limiting the scope thereof:

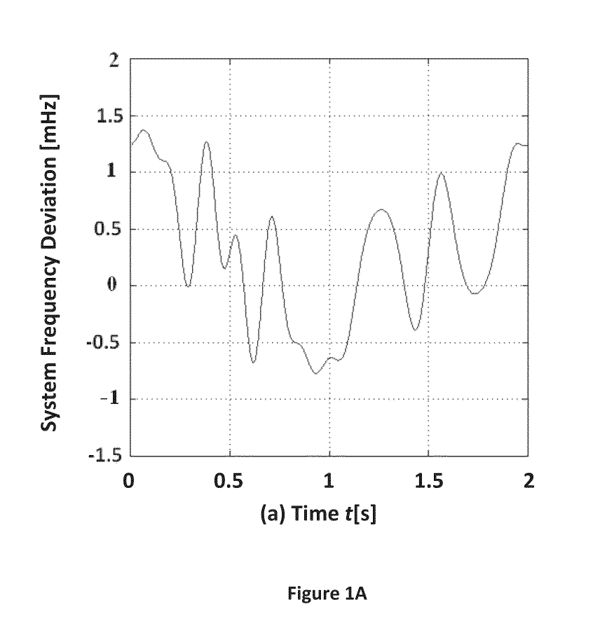

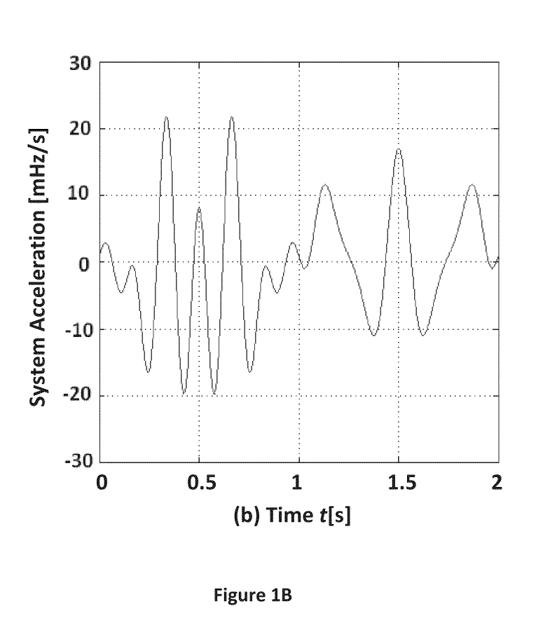

FIG. 1A is a graph of frequency deviation with respect to time for an input signal of raw data. In this example, the data is electrical grid data. The input signal of FIG. 1A does not include noise.

The data represents frequency or, more specifically, the deviation of frequency relative to 60 Hz. As shown in FIG. 1A, the frequency fluctuates up and down slowly because the grid has inertia.

FIG. 1B is a graph of acceleration with respect to time, which is the derivative of the input signal of FIG. 1A. The acceleration, which represents frequency change over time, can be calculated by finding the derivative of frequency by time. The curve of FIG. 1B is a point by point differentiation of the frequency.

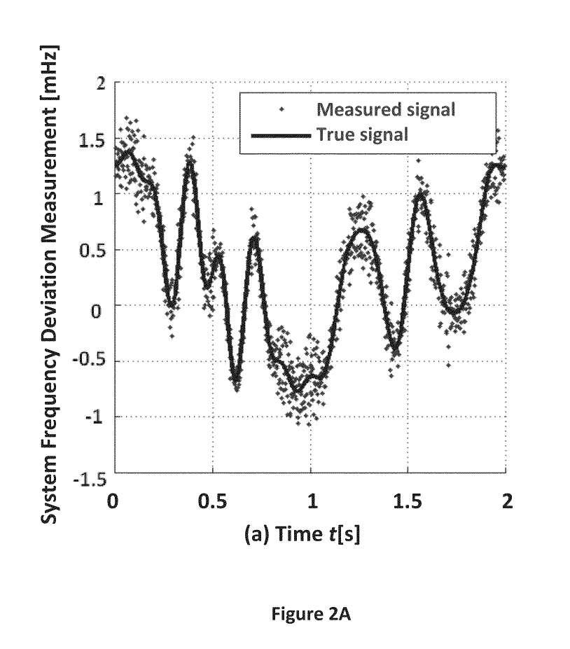

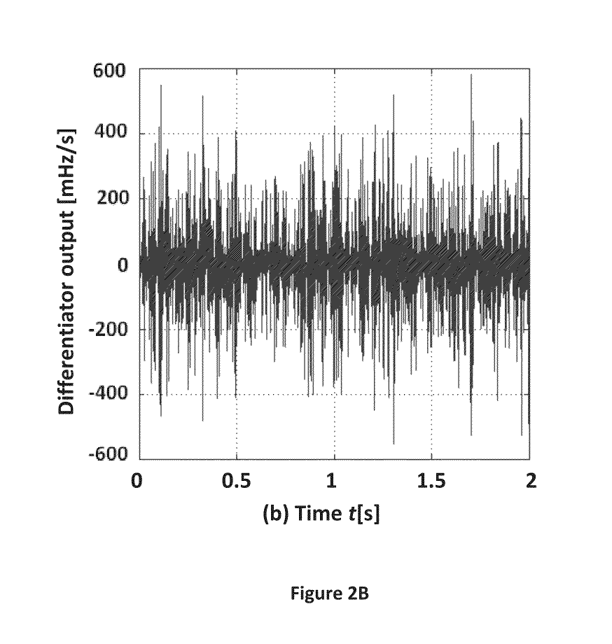

FIG. 2A is a graph showing a true input signal in the presence of noise—or measured signal—with respect to time.

FIG. 2B is a graph showing the output of the conventional differentiator with respect to time of the measured input signal shown in FIG. 2A. Each noise point in FIG. 2A is differentiated to yield the acceleration, which represents noise not the signal. The noise is much higher than the signal. In other words, the signal is hidden because of the noise after differentiation of each noise point.

Based on the desired frequency response, the original signal in this example is below 10 Hz, and the noise is above 175 Hz. At a sampling rate of 512 Hz, the passband edge ωₚ=0.27π Hz and the stopband edge ωₐ=0.57π Hz are suitable values to use for one embodiment of an optimal band-limited differentiator (BLD).

The BLD transfer function coefficients of one embodiment are shown in Table 1.

TABLE 1
Optimal band-limited differentiator coefficients

h_0 = −h_22 = −0.799613
h_1 = −h_21 = −0.680845
h_2 = −h_20 = 2.37278
h_3 = −h_19 = 5.61932
h_4 = −h_18 = 1.1806
h_5 = −h_17 = −12.4947
h_6 = −h_16 = −19.8373
h_7 = −h_15 = 0.616533
h_8 = −h_14 = 46.8053
h_9 = −h_13 = 81.8494
h_10 = −h_12 = 65.5435
h_11 = 0

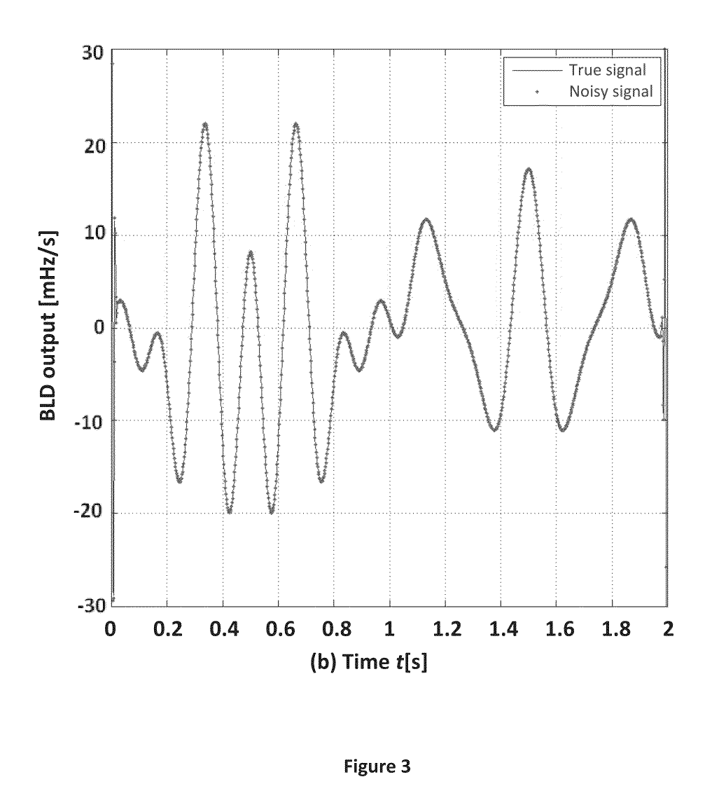

FIG. 3 is a graph showing the output of the band-limited differentiator of the present invention for the true and measured input signals.

The performance of the example optimal band-limited differentiator far exceeds that of the conventional differentiator, as shown in Table 2, which evaluates the signal-to-noise ratio of the test signals, excluding the first and last 0.04 seconds of the signals.

TABLE 2
Signal-to-noise ratios of differentiators

| | Conventional | Band-limited |
|---|---|---|
| SNR = 20 log\|\|s\|\|₂/\|\|n - s\|\|₂ | −25.7 dB | 46.1 dB |

The design of digital differentiators for measuring electrical grid data has been significantly improved using the methods and designs described herein. Many applications exist that may benefit from use of the present methods and designs. For example, so-called grid-friendly appliances sample zero-crossing times of the 60 Hz AC power in homes and use a sliding window average to compute electric grid interconnection frequency to decide whether to shed the appliances' loads following a generator outage. An advantage of the band-limited differentiator is that it would be immune to local noise that can emanate from induction motors and switched power electronic equipment which can mask the slower changes in grid frequency that the controller is designed to respond to.

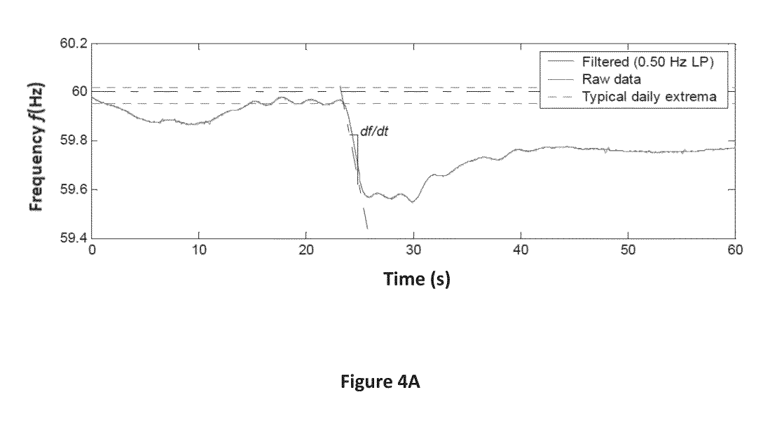

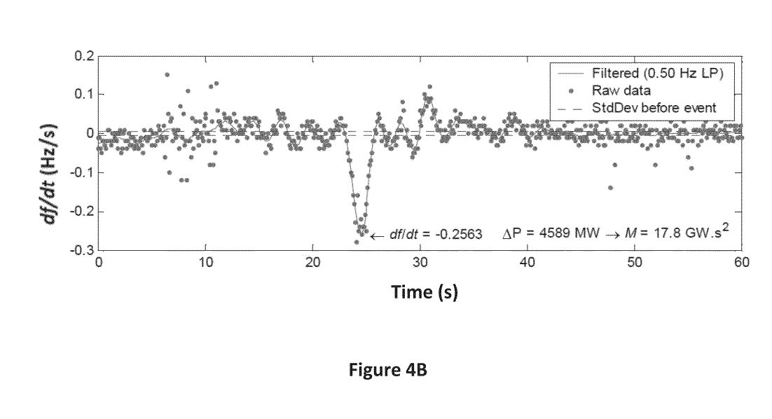

Another application is in estimation of the grid interconnection inertia using local low-cost frequency measurements such as those used in grid-friendly appliance zero-crossing detectors. Significant deviations in frequency occur when there is a large difference between generation and load. During the first few seconds after a major outage, the overall interconnection inertia can be estimated by using the relation:

$$- Δ P = M \frac{d f}{d t}$$

where df/dt is the rate of frequency change in Hz/s, ΔP is the power change per unit (pu) of system load base, and M is the inertial constant in pu.seconds. The inertial property is largely determined by the mix of generators running at the time of the outage. In this example, a conventional 0.5 Hz low-pass filter was used to identify the rate of frequency change with acceptable results as shown in FIGS. 4A and 4B.

FIG. 4A shows the frequency changes for a real frequency measured at 60 Hz using the band-limited differentiator of the present invention with a conventional 0.5 Hz low-pass filter. In FIG. 4A, the data is filtered at approximately 25 seconds.

FIG. 4B shows the derivative of the filtered signal of FIG. 4A using the band-limited differentiator of the present invention. The derivative of the filtered signal is calculated at approximately 25 seconds.

The calculations needed to estimate system inertia are very sensitive to the peak value of the rate of frequency change and thus very sensitive to the quality of the filter used prior to differentiation. Using an optimally designed differentiator such as described herein can significantly improve the overall result of the inertial estimate, thus requiring fewer outages, to provide a reasonably accurate estimate of system inertia as a function of load. This in turn would allow power system engineers to more accurately estimate the evolution of inertia over time, particularly in response to changing generation mix as more wind and solar generation come online, and adjust the probability threshold for activating a grid friendly appliance controller.

While a number of embodiments of the present invention have been shown and described, it will be apparent to those skilled in the art that many changes and modifications may be made without departing from the invention in its broader aspects. The appended claims, therefore, are intended to cover all such changes and modifications as they fall within the true spirit and scope of the invention.

We claim:

1. A method of measuring electrical grid data in the presence of noise, comprising:
a. receiving noisy data from the grid;
b. filtering the noisy data above a predetermined frequency; and
c. differentiating the filtered data using a band-limited differentiator.

2. The method of claim 1 wherein the data is filtered and differentiated simultaneously by the band-limited differentiator.

3. The method of claim 1 wherein the differentiating comprises determining the derivative of the filtered data.

4. The method of claim 1 wherein the predetermined frequency for cutting off noise from the noisy data is at least 0.5 Hz.

5. The method of claim 1 wherein the filtered and differentiated data is used by a grid appliance controller.

6. The method of claim 1 wherein the noisy data includes at least one of the following:
frequency signals and voltage or current signals.

7. The method of claim 1 further comprising estimating inertia of the electrical grid as a function of load.

8. The method of claim 1 further comprising measuring zero-crossing times of approximately 60 Hz AC power in homes.

9. The method of claim 1 wherein the receiving noisy data from the grid comprises measuring instantaneous AC voltage or currents from the grid.

10. The method of claim 1 wherein the band-limited differentiator is a band-limited digital differentiator.

11. A device for measuring electrical grid data in the presence of noise comprising:
a. a band-limited differentiator for filtering noisy data from the grid above a predetermined frequency and differentiating the filtered data; and
b. a grid appliance controller including the band-limited differentiator.

12. The device of claim 11 wherein the differentiator is a digital differentiator.

13. The device of claim 11 wherein the noisy data includes at least one of the following: frequency signals and voltage or current signals.

14. The device of claim 11 wherein the differentiator simultaneously filters and differentiates the data.

15. A method of measuring electrical grid data in the presence of noise, comprising:
a. receiving noisy frequency data from the grid;
b. filtering the noisy frequency data above a frequency of at least 0.5 Hz; and
c. differentiating the filtered data using a band-limited digital differentiator; wherein the data is filtered and differentiated simultaneously by the band-limited digital differentiator.

16. The method of claim 15 wherein the differentiating comprises determining the derivative of the filtered data.

17. The method of claim 15 wherein the filtered and differentiated data is used by a grid appliance controller.

18. The method of claim 15 further comprising estimating inertia of the electrical grid as a function of load.

19. The method of claim 15 further comprising measuring zero-crossing times of approximately 60 Hz AC power in homes.

20. The method of claim 15 wherein the receiving noisy frequency data from the grid comprises measuring instantaneous AC voltage or currents from the grid.
